(19) United States
(12) Patent Application Publication
(10) Pub. No.: US 2015/0228722 A1
(43) Pub. Date: Aug. 13, 2015

(54) SEMICONDUCTOR DEVICE INCLUDING FIN-TYPE FIELD EFFECT TRANSISTOR

(71) Applicant: Samsung Electronics Co., Ltd., Suwon-si (KR)

(72) Inventors: Eun-Ae CHUNG, Hwaseong-si (KR); Gab-Jin NAM, Seoul (KR); Sung-Min KIM, Incheon (KR); Sung-Kweon BAEK, Hwaseong-si (KR); Jin-Soak KIM, Seoul (KR)

(21) Appl. No.: 14/613,070

(22) Filed: Feb. 3, 2015

(30) Foreign Application Priority Data
Feb. 7, 2014 (KR) 10-2014-0014452

(51) Int. Cl. H01L 29/06; H01L 27/088; H01L 29/78

(52) U.S. Cl. CPC H01L 29/0657; H01L 29/7851; H01L 27/0886

(57) ABSTRACT

Provided is a semiconductor device including: a substrate; a first fin-field effect transistor comprising a first fin-type semiconductor layer having a first height and a first width, formed on the substrate; and a second fin-field effect transistor comprising a second fin-type semiconductor layer having a second height and a second width, formed on the substrate. The first fin-field effect transistor and the second fin-field effect transistor are separated by a predetermined distance. The first height is greater than the second height and the first width is less than the second width.

### CROSS-REFERENCE TO RELATED APPLICATIONS

This application claims the benefit of priority to Korean Patent Application No. 10-2014-0014452, filed on Feb. 7, 2014, in the Korean Intellectual Property Office, the disclosure of which is incorporated herein in its entirety by reference.

### BACKGROUND

Example embodiments relate to a semiconductor device, and more particularly, to a semiconductor device including a fin-type field effect transistor.

As the memory capacity of semiconductor devices has increased, a density of the semiconductor devices has also increased to enhance the integrity of semiconductor devices per unit area. A density increase of the semiconductor devices is possible by reducing a size of each semiconductor device and narrowing the gaps between the semiconductor devices. However, if a size of semiconductor that has a horizontal channel is reduced, the horizontal channel is shortened, and thus, a short channel effect may occur. Therefore, a semiconductor device with an effective channel length and increased operating current may be forced by forming a fin on a gate. An example of such a semiconductor device is a fin field effect transistor FinFET.

### SUMMARY

According to some embodiments, the disclosure provides a semiconductor device including a fin-type field effect transistor has a logic semiconductor device and an input/output (I/O) semiconductor device, and a fin type of the logic semiconductor device is different from that of the I/O semiconductor device. Accordingly, the semiconductor device including the fin-type field effect transistor may be used to enhance reliability such as a hot carrier effect of the I/O semiconductor device and improve the performance of the logic semiconductor device.

According to an aspect of the inventive concept, there is provided a semiconductor device including: a substrate; a first fin-field effect transistor including a first fin-type semiconductor layer formed on the substrate, and a first gate structure covering a first portion of the first fin-type semiconductor layer; and a second fin-field effect transistor including a second fin-type semiconductor layer formed on the substrate, and a second gate structure covering a first portion of the second fin-type semiconductor layer. The first fin-field effect transistor and the second fin-field effect transistor are separated by a predetermined distance. The first fin-type semiconductor layer has a first width (w1) between a first surface and a second surface opposite to the first surface in a first direction, and a first height (h1) in a second direction perpendicular to both a top surface of the substrate and the first direction. The second fin-type semiconductor layer has a second width (w2) between a third surface and a fourth surface opposite to the third surface in the first direction, and a second height (h2) in the second direction. A first ratio h1/w1 is greater than a second ratio h2/w2, and the first height (h1) is greater than the second height (h2). The first fin-field effect transistor is formed in a first area where a logic semiconductor device is formed. The second fin-field effect transistor is formed in a second area where an input/output (I/O) semiconductor device is formed.

The first gate structure has a first gate insulating layer and a first gate electrode disposed on the first gate insulating layer, and the second gate structure has a second gate insulating layer formed of a different material from the first gate insulating layer and a second gate electrode disposed on the second gate insulating layer.

The first width (w1) is less than the second width (w2).

The second width (w2) is the width of the second fin-type semiconductor layer at the center of the second height (h2), and the second fin-type semiconductor layer has a tapered shape including a top width at a top surface of the first portion of the second fin-type semiconductor layer and a bottom width at a bottom of the first portion of the second fin-type semiconductor layer, the bottom width greater than the top width.

The first ratio h1/w1 of the first fin-type semiconductor layer may be in a range from about 3.5 to about 9.

Each of the first and second fin-type semiconductor layers includes a source region and a drain region, and the first portion of the first fin-type semiconductor layer and the first portion of the second fin-type semiconductor layer are each a channel area disposed between corresponding source region and drain regions.

Each channel area may be formed of at least one of silicon (Si), doped silicon, germanium (Ge), and a group III-V semiconductor materials.

According to another aspect of the inventive concept, there is provided a semiconductor device including: a substrate; a first fin-field effect transistor including a first fin-type semiconductor layer formed on the substrate, and a first gate electrode covering a first portion of the first fin-type semiconductor layer, the first portion having a first height (h1) between a top surface and a bottom surface of the first fin-type semiconductor layer in a first direction, and having a first width (w1) between a first surface and a second surface opposite to the first surface of the first fin-type semiconductor layer in a second direction perpendicular to the first direction and parallel to a top surface of the substrate; and a second fin-field effect transistor including a second fin-type semiconductor layer formed on the substrate, and a second gate electrode covering a first portion of the second fin-type semiconductor layer, the first portion having a second height (h2) between a top surface and a bottom surface of the second fin-type semiconductor layer in the first direction, and having a second width (w2) at the center of the second height (h2) between a third surface and a fourth surface opposite to the third surface of the second fin-type semiconductor layer in the second direction. A width at the top surface of the first fin-type semiconductor layer between the first surface and the second surface of the first fin-type semiconductor layer is substantially the same as a width at the bottom surface of first fin-type semiconductor layer between the first surface and the second surface of the first fin-type semiconductor layer, and a width at the top surface of the second fin-type semiconductor layer between the third surface and the fourth surface of the second fin-type semiconductor layer is less than a width at the bottom surface of second fin-type semiconductor layer between the third surface and the fourth surface of the second fin-type semiconductor layer.

The first fin-field effect transistor and the second fin-field effect transistor are separated by a predetermined distance.

The first fin-field effect transistor may be formed in a first area where a logic semiconductor device is formed, and the second fin-field effect transistor may be formed in a second area where an input/output (I/O) semiconductor device is formed.

A height of the first fin-type semiconductor layer in the first direction may be a greater than that of the second fin-type semiconductor layer.

A width of the first fin-type semiconductor layer in the second direction may be a less than a width average value of the second fin-type semiconductor layer in the second direction.

An angle between the third or the fourth surface of the second fin-type semiconductor layer and the top surface thereof may be between about 60 degrees and about 85 degrees.

An aspect ratio h2/w2 of the second fin-type semiconductor layer may be smaller than an aspect ratio h1/w1 of the first fin-type semiconductor layer.

The aspect ratio h2/w2 of the second fin-type semiconductor layer may be between about 2.5 and about 4.

According to still another aspect of the inventive concept, there is provided a semiconductor device including: a substrate including a top surface and a bottom surface; a logic circuit including one or more logic transistors; an input/output circuit including one or more input/output transistors; a first fin-field effect transistor including a first source, a first drain, a first channel disposed between the first source and the first drain, and a first gate structure covering the first channel, the first channel having a first width (w1) in a first direction parallel to the top surface of the substrate and a first height (h1) in a second direction perpendicular to the first direction; a second fin-field effect transistor including a second source, a second drain, a second channel disposed between the second source and the second drain, and a second gate structure covering the second channel, the second channel having a second width (w2) in the first direction and a second height (h2) in the second direction. The first height (h1) is greater than the second height (h2), and the first width (w1) is less than the second width (w2).

### BRIEF DESCRIPTION OF THE DRAWINGS

Exemplary embodiments of the inventive concept will be more clearly understood from the following detailed description taken in conjunction with the accompanying drawings in which:

FIG. 1 is an exemplary perspective view of a semiconductor device including a fin field effect transistor according to an embodiment;

FIG. 2 is a cross-sectional view taken along a line A-A′ of the semiconductor device including the fin field effect transistor of FIG. 1 according to an exemplary embodiment;

FIG. 3 is a plan view of the semiconductor device of FIG. 1 according to an embodiment;

FIG. 4 is an exemplary cross-sectional view of a semiconductor device including a fin field effect transistor according to an embodiment;

FIGS. 5 through 8 are cross-sectional views for explaining a method of manufacturing the semiconductor device including the fin field effect transistor of FIG. 1, according to example embodiments;

FIG. 9 is a partial cross-sectional view for explaining a part of a method of manufacturing the semiconductor device including a fin field effect transistor according to an exemplary embodiment;

FIG. 10 is a partial cross-sectional view for explaining a method of manufacturing a semiconductor device including a fin field effect transistor, according to an exemplary embodiment;

FIG. 11 is a partial cross-sectional view for explaining another method of manufacturing a semiconductor device, according to an exemplary embodiment; and

FIG. 12 is a block diagram of an electronic system including semiconductor devices, according to certain embodiments.

### DETAILED DESCRIPTION OF THE EMBODIMENTS

Hereinafter, the disclosure will be described in detail by explaining exemplary embodiments of the invention with reference to the attached drawings.

The invention may, however, be embodied in many different forms and should not be construed as being limited to the embodiments set forth herein.

The terms used in the present specification are merely used to describe particular embodiments, and are not intended to limit the inventive concept. An expression used in the singular encompasses the expression in the plural, unless it has a clearly different meaning in the context. In the present specification, it is to be understood that the terms such as “comprises,” “comprising,” “includes,” and/or “including,” when used herein, are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It will be understood that although the terms “first”, “second”, etc. may be used herein to describe various components, these components should not be limited by these terms. Unless indicated otherwise, these components are only used to distinguish one component from another. For example, a first component may be a second component, and similarly, the second component may be the first component.

As used herein, the singular terms “a,” “an” and “the” are intended to include the plural forms as well, unless the context clearly indicates otherwise. Expressions such as “at least one of,” when preceding a list of elements, modify the entire list of elements and do not modify the individual elements of the list. As used herein, the term “and/or” includes any and all combinations of one or more of the associated listed items. It will be understood that when an element is referred to as being “connected” or “coupled” to another element, it may be directly connected or coupled to the other element or intervening elements may be present. The term “contact,” as used herein, refers to a direct contact, unless indicated otherwise.

Unless the context indicates otherwise, terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to limit the scope of example embodiments.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the drawings, the thicknesses of layers and regions are exaggerated for clarity. Like reference numerals in the drawings denote like elements, and thus, their description will not be repeated. In the drawings, a dotted line or a solid line is used to indicate that elements are formed of different membranous layers, and does not specify their physical property or an exterior thereof.

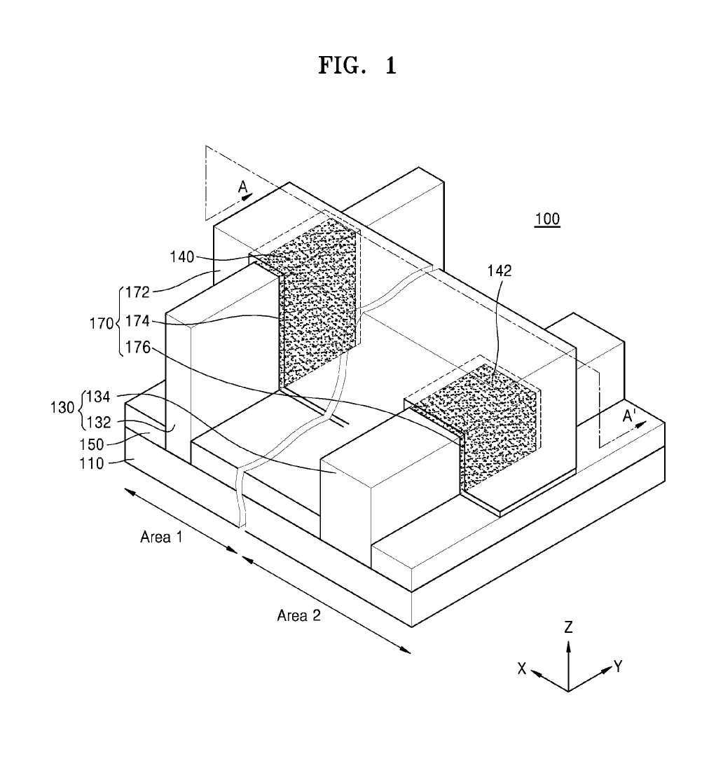

FIG. 1 is an exemplary perspective view of a semiconductor device 100 including a fin field effect transistor according to an embodiment.

As used herein, a semiconductor device may refer to any of the various devices such as shown in FIGS. 1-11, and may also refer, for example, to two transistors or a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

An electronic device, as used herein, may refer to these semiconductor devices, but may additionally include products that include these devices, such as a memory module, a hard drive including additional components, or a mobile phone, laptop, tablet, desktop, camera, or other consumer electronic device, etc.

Referring to FIG. 1, the fin field effect transistor of the semiconductor device 100 has dual fin-type semiconductor layers. In detail, the semiconductor device 100 may include a substrate 110, an isolation layer 150 formed on the substrate 110, fin-type semiconductor layers 130 including a first fin-type semiconductor layer 132 and a second fin-type semiconductor layer 134, a gate electrode 172, a first gate insulating layer 174, and a second gate insulating layer 176.

The substrate 110 may be formed of silicon (Si) such as crystalline silicon, polycrystalline silicon, or amorphous silicon. In other embodiments, the substrate 110 may include a compound semiconductor formed of, for example, germanium (Ge), silicon germanium (SiGe), silicon carbide (SiC), gallium arsenide (GaAs), indium arsenide (InAs), or indium phosphorus (InP). In one embodiment, the substrate 110 may have a silicon-on-insulator (SOI) structure. For instance, the substrate 110 may include a buried oxide (BOX) layer. In some embodiments, the substrate 110 may include a conductive area, for example, a well doped with impurities or a structure doped with impurities.

The fin-type semiconductor layers 130 extend parallel to each other along one direction (a Y direction of FIG. 1). The isolation layer 150 is formed between the fin-type semiconductor layers 130 that are disposed on the substrate 110. The fin-type semiconductor layers 130 extend on the substrate 110 in a direction (a Z direction of FIG. 1) perpendicular to the substrate 110.

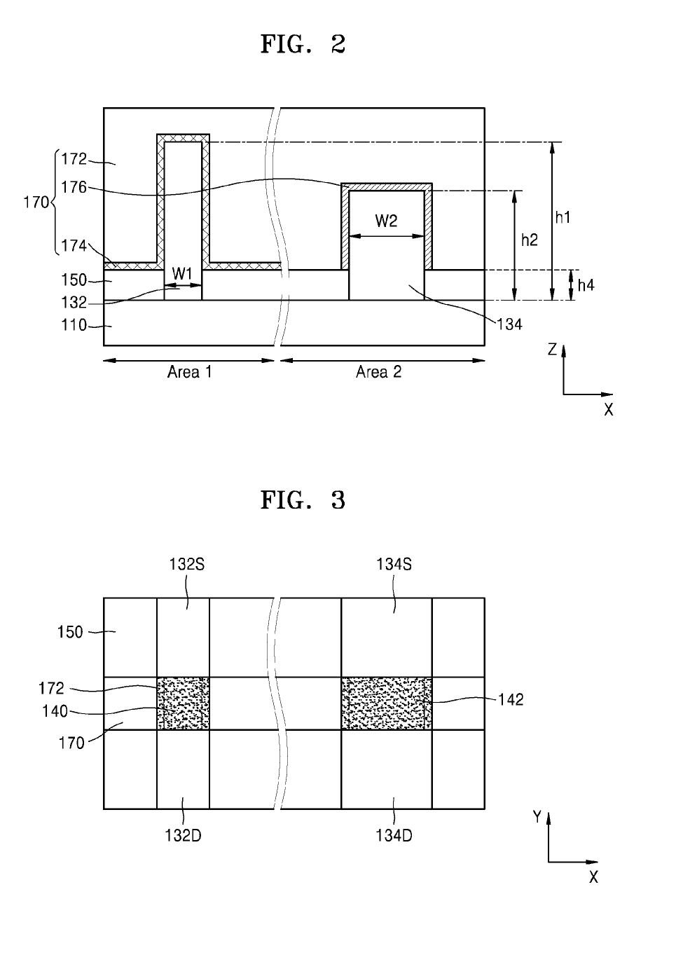

The fin-type semiconductor layers 130 have different forms and are separated from one another by a predetermined distance. A ratio between a width of the fin-type semiconductor layers 130 measured in a direction (an X direction of FIG. 1) parallel to a top surface of the substrate 110 and a height of the fin-type semiconductor layers 130 measured in the direction (the Z direction of FIG. 1) perpendicular to the substrate 110, that is, aspect ratios, are different from each other. In one embodiment, a width of the first fin-type semiconductor layer 132 is less than that of the second fin-type semiconductor layer 134 disposed at the same level, but a height of the first fin-type semiconductor layer 132 may be greater than that of the second fin-type semiconductor layer 134. In addition, an aspect ratio of the first fin-type semiconductor layer 132 may be greater than that of the second fin-type semiconductor layer 134. The widths, heights, and aspect ratios of the first fin-type semiconductor layer 132 and the second fin-type semiconductor layer 134 will be further explained later with reference to FIG. 2.

A gate structure 170 on the isolation layer 150 disposed on the substrate 110 covers a top surface and both side surfaces of the fin-type semiconductor layers 130 and extends in the direction (the X direction of FIG. 1) perpendicular to the fin-type semiconductor layers 130. For example, the gate structure 170 may cover a portion of the fin-type semiconductor layers 130. A plurality of fin field effect transistors (FinFETs) may be formed by including the fin-type semiconductor layers 130 and the gate structure 170. The gate structure 170 includes the first gate insulating layer 174 covering the top surface and the side surfaces of the fin-type semiconductor layers 130, and a gate electrode 172 that is disposed on the first gate insulating layer 174 covers the top surface and the side surfaces of the fin-type semiconductor layers 130 and may extend to cross the fin-type semiconductor layers 130.

The gate electrode 172 is disposed on the first gate insulating layer 174 and extends to cover the top surface and the side surfaces of the fin-type semiconductor layers 130. The gate electrode 172 may be formed of polycrystalline silicon or a conductive material doped with metals such as aluminium (Al), nickel (Ni), tungsten (W), titanium (Ti) and tantalum (Ta).

The first gate insulating layer 174 may be formed of a high dielectric film having a high dielectric constant greater than that of a silicon oxide layer. For example, the first gate insulating layer 174 may be formed of a high dielectric constant film (a high-k film) having a dielectric constant from about 10 to about 25.

For example, each of the first and second fin-type semiconductor layers 132 and 134 may include a source, a drain, and a channel disposed between the source and the drain.

Channel areas 140 and 142 are formed where the gate electrode 172 covers a portion of the first fin-type semiconductor layer 132 and the second fin-type semiconductor layer 134. The channel areas 140 and 142 may be formed of a semiconductor material such as Si, doped Si, Ge and SiGe, or a group III-V compound semiconductor including, for example, GaAs, InAs or InP.

A length of each of the channel areas 140 and 142 is determined according to a length of a surface on which the first and second fin-type semiconductor layers 132 and 134 contact the gate electrode 172. For example, the length of each of the channel areas 140 and 142 may be defined as extending in the Y direction.

A width of each of the channel areas 140 and 142 is determined between a first surface and a second surface opposite to the first surface of the first and second fin-type semiconductor layers 132 and 134 in the X direction. For example, a first width of the channel area 140 may be defined as a distance between a first surface and a second surface opposite to the first surface of the first fin-type semiconductor layer 132 in the X direction, and a second width of the channel area 142 may be defined as a distance between a third surface and a fourth surface opposite to the third surface of the second fin-type semiconductor layer 134 in the X direction. These first through fourth surfaces may be described as sidewall surfaces. For example, the surface on which the first and second fin-type semiconductor layers 132 and 134 contact the gate electrode 172 may have a ‘ [symbol] ’ shape (or an upside down “U” shape).

A height of each of the channel areas 140 and 142 is determined between a top surface and a bottom surface of each of the first and second fin-type semiconductor layers 132 and 134 in the Z direction. For example, a first height of the channel area 140 may be defined as a distance between a top surface and a bottom surface of the first fin-type semiconductor layer 132 in the Z direction, and a second height of the channel area 142 may be defined as a distance between a top surface and a bottom surface of the second fin-type semiconductor layer 134 in the Z direction.

In the present embodiment, the height of the first fin-type semiconductor layer 132 is greater than that of the second fin-type semiconductor layer 134, and the width of the first fin-type semiconductor layer 132 is less than that of the second fin-type semiconductor layer 134. The width of the channel area 140 formed between the first fin-type semiconductor layer 132 and the gate electrode 172 may be less than that of the channel area 142 formed between the second fin-type semiconductor layer 134 and the gate electrode 172.

The first fin-type semiconductor layer 132 and the gate structure 170 formed on the substrate 110 is formed in a first area, and the second fin-type semiconductor layer 134 and the gate structure 170 may be formed in a second area. The first area is separated from the second area by a predetermined distance. In the present embodiment, the first area may include a logic semiconductor device, for example, a core transistor, a logic transistor, or a low power transistor, and the second area may include an input/output semiconductor device or an interface semiconductor device, for example, input/output transistor, an analog transistor or a high power transistor.

In one embodiment, the semiconductor device 100 includes a FinFET including a first fin-type semiconductor layer and a FinFET including a second fin-type semiconductor layer different from the first fin-type semiconductor layer. Thus, the fin-type semiconductor layers 130 may have different fin scaling profiles, thereby improving the controllability of an integrated gate. In detail, the logic semiconductor device formed in the first area is mainly used for a low-power operation device such as a graphic card chip or a mobile application processor and is a device that actually performs operations as a central processing unit (CPU) operates. For example, an active current compared to a leakage current is an important factor for the performance of the semiconductor device 100. For example, a semiconductor device may require a high effective current value even though a leakage current is high. A chip used as a graphic card needs to have a smaller leakage current than that of an arithmetic operation semiconductor device, but may require an effective current value that is equal to or greater than a certain value. Also, since both an effective current value and power consumption of a mobile application processor are important, the mobile application processor needs to maintain a leakage current value to be smaller than a certain value.

In one embodiment, an input/output semiconductor device (e.g., an input/output transistor) formed in the second area is a device that receives an external voltage, that is, performs other functions such as interface-communication with, for example, a memory device. The input/output semiconductor device receives the external voltage, and various data are input/output in response thereto. Therefore, unless the external voltage changes, an input/output operation voltage does not need to be changed, and thus a gate length of the input/output transistor does not need to be changed. For example, if an input/output operation voltage and the gate length of the input/output transistor are decreased, an output desired by a user may not be produced. Therefore, unlike the logic semiconductor device, the input/output semiconductor device may have a gate length and an operation voltage that does not change. However, if the input/output semiconductor device is of the same fin type as the logic semiconductor device, a reliability problem, for example, a hot carrier effect, may occur. In the semiconductor device 100, the aspect ratio of the first fin-type semiconductor layer 132 functioning as the logic semiconductor device is different from that of the second fin-type semiconductor layer 134 functioning as the input/output semiconductor device, and thus, maintaining of the effective current value of the logic semiconductor device and a design consuming low power may be possible, and the reliability problem of the input/output semiconductor device, for example, the hot carrier effect, may also be solved.

FIG. 2 is a cross-sectional view taken along a line A-A′ of the semiconductor device 100 including the FinFET of FIG. 1 according to an exemplary embodiment.

Referring to FIG. 2, the semiconductor device 100 may include the substrate 110, the isolation layer 150 formed on the substrate 110, the first fin-type semiconductor layer 132, the second fin-type semiconductor layer 134, the gate electrode 172, the first gate insulating layer 174, and the second gate insulating layer 176. Hereinafter, the components described with reference to FIG. 1 will be not be described again.

In the present embodiment, a top width of the first fin-type semiconductor layer 132 is the same as a bottom width thereof, and a top width of the second fin-type semiconductor layer 134 is the same as a bottom width thereof. The top and bottom widths are measured based on a direction (an X direction of FIG. 2) parallel to a top surface of the substrate 110, and each of the first and second fin-type semiconductor layers 132 and 134 may have a rectangular shape having a vertical angle formed between a top surface and a side surface thereof, for example, about 90 degrees. In some embodiments, a cross-section of the first and second fin-type semiconductor layers 132 and 134 is not limited to a rectangular shape, and the top surface thereof may have a circular shape or a curved shape with a projected top.

The first fin-type semiconductor layer 132 protrudes upwards a first height h1 in a direction (a Z direction of FIG. 2) perpendicular to the top surface of the substrate 110 and is formed to have a first width w1 along the direction (the X direction of FIG. 2) parallel to the top surface of the substrate 110. The second fin-type semiconductor layer 134 protrudes upwards a second height h2 in the direction (the Z direction of FIG. 2) perpendicular to the substrate 110 and is formed to have a second width w2 along the direction (the X direction of FIG. 2) parallel to the top surface of the substrate 110. In addition, a height of the first fin-type semiconductor layer 132 may be defined as a distance between the top surface of the isolation layer 150 and the top surface of the first fin-type semiconductor layer 132 in the Z direction (e.g., h1-h4), and a height of the second fin-type semiconductor layer 134 may be defined as a distance between the top surface of the isolation layer 150 and the top surface of the second fin-type semiconductor layer 134 in the Z direction (e.g., h2-h4).

In one embodiment, the first height h1 of the first fin-type semiconductor layer 132 is greater than the second height h2 of the second fin-type semiconductor layer 134. In addition, the first width w1 may be less than the second width w2 of the second fin-type semiconductor layer 134.

In the present embodiment, the first and second fin-type semiconductor layers 132 and 134 may have different ratios of the widths w1 and w2 to heights h1 and h2, respectively, for example, different aspect ratios. In detail, the aspect ratio of the first fin-type semiconductor layer 132 is defined as the first height h1 divided by the first width w1, and that of the second fin-type semiconductor layer 134 is defined as the second height h2 divided by the second width w2. In some embodiments, the aspect ratio of the first fin-type semiconductor layer 132, for example, the first height h1 divided by the first width w1, may be equal to or greater than 3.5.

The first height h1 divided by the first width w1, which is the aspect ratio of the first fin-type semiconductor layer 132, may be greater than the second height h2 divided by the second width w2, which is the aspect ratio of the second fin-type semiconductor layer 134. For example, the shape of the first fin-type semiconductor layer 132 is vertically longer and thinner than that of the second fin-type semiconductor layer 134 in a relative sense.

FIG. 3 is a plan view of the semiconductor device 100 of FIG. 1 according to an embodiment.

Referring to FIG. 3, the first and second fin-type semiconductor layers 132 and 134 extend in a Y direction, and the gate electrode 172 may be formed to extend and vertically cross the first fin-type semiconductor layer 132 and the second fin-type semiconductor layer 134 along an X direction. As illustrated in FIG. 1, the width of the first fin-type semiconductor layer 132 that is measured in the X direction of FIG. 1 may be less than that of the second fin-type semiconductor layer 134 that is measured in the X direction of FIG. 1. The channel areas 140 and 142 may each be formed on the surface on which the first fin-type semiconductor layer 132, the second fin-type semiconductor layer 134 and the gate electrode 172 contact. The first area including the logic semiconductor device may be separated from the second area including the input/output semiconductor device by a predetermined distance.

The first and second fin-type semiconductor layers 132 and 134 may each have source regions 132S and 134S and drain regions 132D and 134D. The source regions 132S and 134S and the drain regions 132D and 134D may be formed by doping the first and second fin-type semiconductor layers 132 and 134 with impurities.

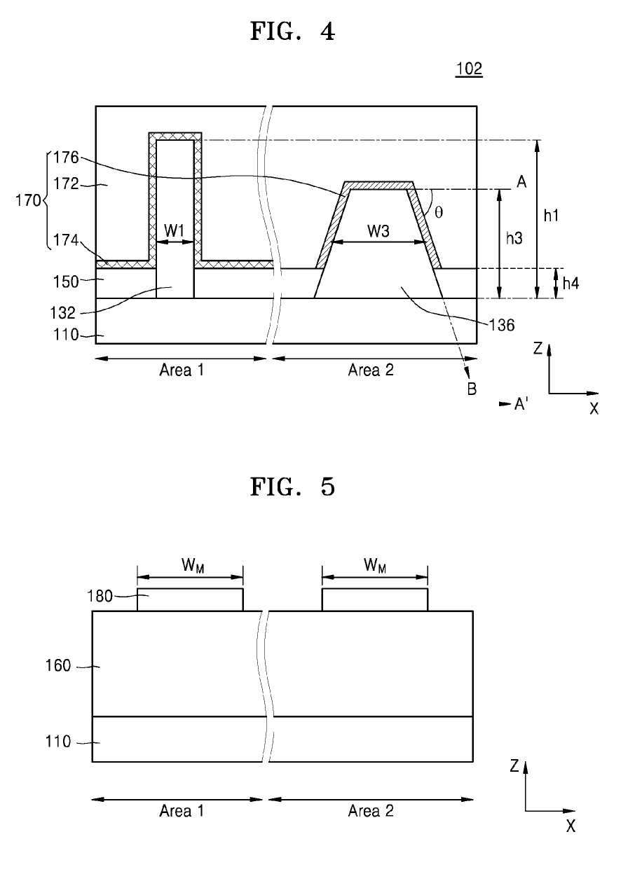

FIG. 4 is an exemplary cross-sectional view of a semiconductor device 102 including a FinFET according to an embodiment.

Referring to FIG. 4, the semiconductor device 102 may include a substrate 110, an isolation layer 150 formed on the substrate 110, a first fin-type semiconductor layer 132, a second fin-type semiconductor layer 136, and a gate structure 170 including a gate electrode 172, a first gate insulating layer 174, and a second gate insulating layer 176. Hereinafter, like reference numerals denote like elements, and repeated descriptions will be omitted.

The semiconductor device 100 of FIG. 1 is different from the semiconductor device 102 of FIG. 4 in the shape of a second fin-type semiconductor layer 136. The first fin-type semiconductor layer 132 has a vertically long rectangular shape, whereas the second fin-type semiconductor layer 136 has a tapered shape with a top width less than a bottom width. In detail, an angle between an extension A extending from a top surface of the second fin-type semiconductor layer 136 in parallel to the top surface of the surface 110 and an extension B extending from the top surface of the second fin-type semiconductor layer 136 to the top surface of the substrate 110 may be smaller than 90 degrees. In the present embodiment, the angle between the extension A and the extension B may be in a range from, for example, about 80 degrees to 90 degrees, or about 60 degrees to 85 degrees. In one embodiment, the angle of the second fin-type semiconductor layer 136 may be formed by adjusting an etching gas or a power used when the etching process is processed.

A channel area of each of the first and second fin-type semiconductor layers 132 and 134 is disposed where the gate structure 170 covers each of the first and second fin-type semiconductor layers 132 and 134.

The first fin-type semiconductor layer 132 protrudes upwards a first height h1 from the top surface of the substrate 110 in a direction (a Z direction of FIG. 4) and is formed to have the first width w1 in a direction (an X direction of FIG. 4) parallel to the top surface of the surface 110. The second fin-type semiconductor layer 136 protrudes upwards a third height h3 from the top surface of the substrate 110 in the Z direction perpendicular to the substrate 110 and is inclined to have a top width that is less than a bottom width of the second fin-type semiconductor layer 136. Since the top and bottom widths of the second fin-type semiconductor layer 136 are not constant, a third width w3 is defined as a value obtained by adding a minimum value of the top width to a maximum value of the bottom width and dividing the addition result by two, for example, an average value. The first height h1 that is a height value of the first fin-type semiconductor layer 132 is formed to be greater than the third height h3 that is a height value of the second fin-type semiconductor layer 136. Also, the first width w1 of the first fin-type semiconductor layer 132 is formed to be less than the third width w3 of the second fin-type semiconductor layer 136 that is measured in a direction parallel to the top surface of the substrate 110.

In addition, a height of the first fin-type semiconductor layer 132 may be defined as a distance between the top surface of the isolation layer 150 and the top surface of the first fin-type semiconductor layer 132 in the Z direction (e.g., h1 −h4), and a height of the second fin-type semiconductor layer 136 may be defined as a distance between the top surface of the isolation layer 150 and the top surface of the second fin-type semiconductor layer 136 in the Z direction (e.g., h3-h4).

In the present embodiment, a ratio between the first height h1 and the first width w1, for example, the aspect ratio of the first fin-type semiconductor layer 132, is different from an aspect ratio between the third height h3 and the third width w3 of the second fin-type semiconductor layer 136.

In one embodiment, the ratio between the first width w1 and the first height h1 of the first fin-type semiconductor layer 132, and a ratio between the third width w3 and the third height h3 of the second fin-type semiconductor layer 136, for example, aspect ratios are different. The aspect ratio of the first fin-type semiconductor layer 132 may be equal to the first height h1 divided by the first width w1, and the aspect ratio of the second fin-type semiconductor layer 136 may be equal to the third height h3 divided by the third width w3. In some embodiments, the third height h3 divided by the third width w3, which is the aspect ratio of the second fin-type semiconductor layer 136, is in a range from about, for example, 2.5 to about 4.

The first height h1 divided by the first width w1, which is the aspect ratio of the first fin-type semiconductor layer 132, may be greater than the third height h3 divided by the third width w3 which is the aspect ratio of the second fin-type semiconductor layer 136. For example, the shape of the first fin-type semiconductor layer 132 may be relatively vertically longer than the second fin-type semiconductor layer 136.

In the present embodiment, the first area may include a logic or arithmetic semiconductor device, and the second area may include an input/output semiconductor device or an interface semiconductor device as illustrated in FIG. 1.

With regard to the semiconductor device 102 having a FinFET of a first fin type and a FinFET of a second fin type different from the first fin type, as the second fin-type semiconductor layer 136 has a tapered shape with the top width less than the bottom width, an effect similar to an effect of a fin-type semiconductor layer having a vertical structure and a small aspect ratio (refer to the second fin-type semiconductor layer 134 of FIG. 1) may be obtained. In one embodiment, the bottom width may be measured either at the top surface of the isolation layer 150 or at the top surface of the substrate 110.

If an input/output semiconductor device has a vertical fin structure and a large aspect ratio, a short channel effect may be improved in comparison with an inclined fin structure. However, if a high gate voltage is applied to the input/output semiconductor device, a problem such as a hot carrier effect, that is, carriers are confined within a fin-type sidewall, may occur. Therefore, if a fin of the input/output semiconductor device is inclined in comparison with a fin of the logic semiconductor device, the input/output semiconductor device may respond to a gate length and an operation voltage according to an external voltage, and also the above-described problem may also be solved, thereby improving the reliability of the input/output semiconductor device.

FIGS. 5 through 10 are cross-sectional views for explaining a method of manufacturing the semiconductor device 100 of FIG. 1, according to example embodiments.

Referring to FIG. 5, the first area of the substrate 110 may include a semiconductor device with regard to a logic or an arithmetic operation, and the second area may include a semiconductor device with regard to an input/output or an interface. Detailed descriptions about the substrate 110 have already been provided with reference to FIG. 1.

An active layer 160 is formed on the substrate 110, and a fin-type mask 180 is patterned on the active layer 160. The active layer 160 may include a plurality of fin-type semiconductor layers (refer to 130 of FIG. 1) obtained through an etching process. The active layer 160 may include, for example, crystalline silicon, polycrystalline silicon, or amorphous silicon. In some embodiments, the active layer 160 may be formed of a compound semiconductor material including, for example, SiGe or SiC, etc. In some embodiments, the active layer 160 may include a P-type impurity diffusion area and an N-type impurity diffusion area.

The fin-type mask 180 may be formed on the substrate 110 in a direction (an X direction of FIG. 5) parallel to the top surface of the surface 110, and a size of the fin-type mask 180 is equal to about a mask width (W_{M}). The fin-type mask 180 may be formed of a material having an etch selectivity compared to the active layer 160. For example, the fin-type mask 180 may be formed of at least one insulating layer selected from among a silicon oxide layer, a silicon nitride layer and a combination thereof.

A fin-type semiconductor layer is formed by etching the active layer 160 and by using the fin-type mask 180 as a resistance layer. In some embodiments, the etching process may be a back-etching process using a wet-etch method using at least one etchant selected from the group consisting of potassium hydroxide (KOH) and tetramethyl ammonium hydroxide (TMAH).

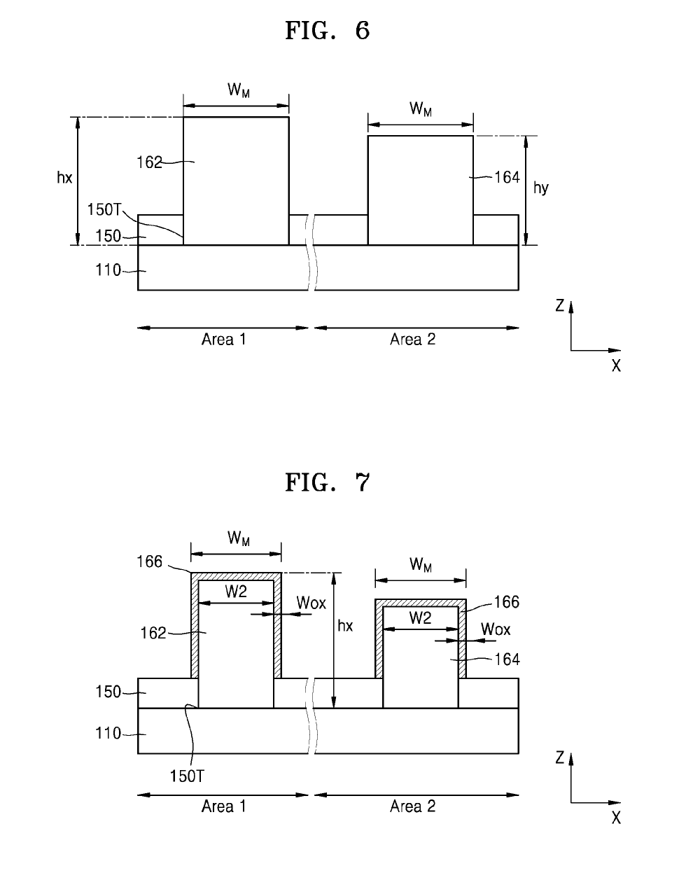

Referring to FIG. 6, a first fin-type active layer 162 and a second fin-type active layer 164 are formed through the above-described process, and then the isolation layer 150 that contacts portions of side surfaces of the first and second fin-type active layers 162 and 164 and the top surface of the substrate 110 is formed. Since the first fin-type active layer 162 is separated from the second fin-type active layer 164 by a predetermined distance, a height of the first fin-type active layer 162 may be different from that of the second fin-type active layer 164 according to use of a mask and a degree of etching during the above-described etching process. The height of the first fin-type active layer 162 is the same as a first active layer height hx, and that of the second fin-type active layer 164 may be the same as a second active layer height hy. In the present embodiment, the first active layer height hx may be greater than the second active layer height hy.

The isolation layer 150 may be formed of at least one insulating layer selected from among, for example, a silicon oxide layer, a silicon nitride layer, a silicon oxynitride layer, and combinations thereof. In some embodiments, isolation layers 150 may include an insulating liner formed of a thermal oxidation layer and a buried insulating layer in which a bottom of a trench 150T for separating the first and second fin-type active layers 162 and 164 is buried on the insulating liner.

The isolation layer 150 first forms insulating layers covering entire top and side surfaces of the first and second fin-type active layers 162 and 164, and flattens top surfaces of the insulating layers through chemical mechanical polishing until the top surfaces of the fin-type active layers 162 and 164 are exposed. Then, the insulating layers may be formed by back-etching in order to ensure that the insulating layers remains thereon by contacting a bottom sidewall of the trench 150T for separating the first and second fin-type active layers 162 and 164.

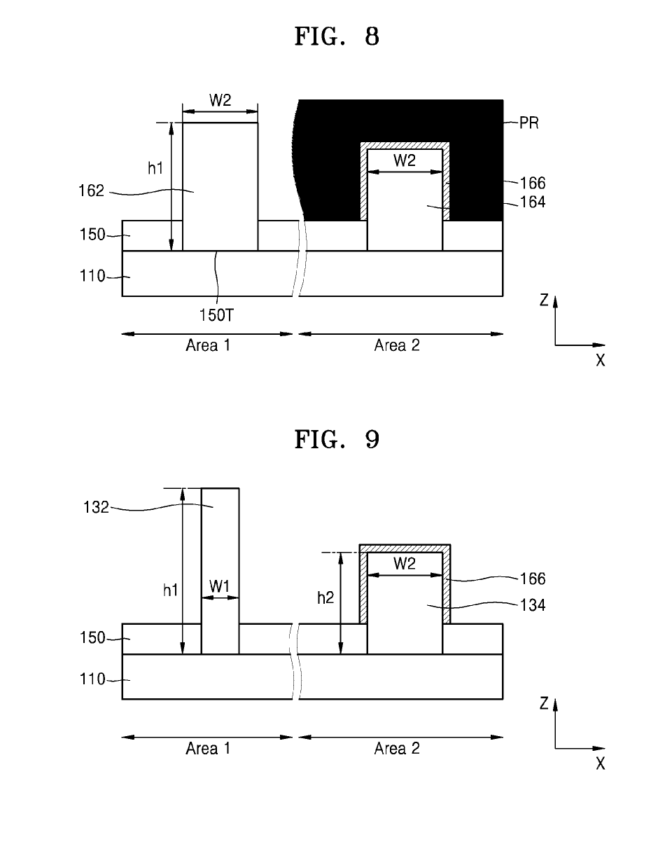

Referring to FIG. 7, a sacrificial oxide layer 166 is formed by oxidizing some portions of the top and side surfaces of the first and second fin-type active layers 162 and 164.

In the present embodiment, since the first and second fin-type active layers 162 and 164 may be formed of at least one type of silicon selected from the group consisting of, for example, crystalline silicon, polycrystalline silicon and amorphous silicon, the sacrificial oxide layer 166 may be formed by oxidizing the silicon through thermal oxidation. A thickness of the sacrificial oxide layer 166 that is measured in a direction (an X direction of FIG. 7) parallel to the top surface of the surface 110 may have a value 2Wox that is a mask width W_{M} subtracted from the second width w2.

Due to the formation of the sacrificial oxide layer 166 via the above-described thermal oxidation, the fin-type active layers 162 and 164 may be reduced to a size of the second width w2 in the direction (the X direction of FIG. 7) parallel to the top surface of the surface 110.

Referring to FIG. 8, a photoresist PR covering the top and side surfaces of the second fin-type active layer 164 formed in the second area is formed, and the sacrificial oxide layer 166 formed on the top and side surfaces of the first fin-type active layer 162 is removed.

The photoresist PR may be formed to cover the second area through lithography or may be formed by applying open photoresist only on the first area after the photoresist PR is formed on the first area and the second area.

Then, the sacrificial oxide layer (refer to 166 of FIG. 7) covering the top and side surfaces of the first fin-type active layer 162 is selectively removed. In the present embodiment, since the sacrificial oxide layer 166 may be a silicon oxide layer, the sacrificial oxide layer 166 may be removed through the wet-etch method using an etchant having etch selectivity compared to crystalline silicon, polycrystalline silicon, amorphous silicon, etc. By removing the sacrificial oxide layer 166, the first fin-type active layer 162 may have the second width w2 and the first height h1 in the direction parallel to the top surface of the surface 110.

Referring to FIG. 9, the photoresist PR (refer to FIG. 8) formed in the second area is removed, and the first fin-type semiconductor layer 132 is formed by etching the first fin-type active layer 162 of FIG. 8.

By removing the photoresist PR formed on the second area through an ashing process or a strip process, the second fin-type active layer 164 and the sacrificial oxide layer 166 formed on the top and side surfaces of the second fin-type active layer 164 are exposed.

Then, the first fin-type active layer 162 is etched by applying a solution which has an etch selectivity to a silicon oxide layer and only etches a silicon layer on the first area and the second area and performing a wet-etch process. Thus, the first fin-type active layer 162 has a small width w1.

In some embodiments, an etching method may be an isotropic etching method using at least one etchant of scandium (SC1), ammonium hydroxide (NH4OH), KOH, and TMAH. When the isotropic etching method is used, both side surfaces of the first fin-type active layer 162 are etched and the width thereof may be reduced without a height change. Accordingly, the first fin-type active layer 162 may be formed as the first fin-type semiconductor layer 132 having the first width w1 and the first height h1. The second fin-type active layer 164 (refer to FIG. 8) formed on the second area may be formed as the second fin-type semiconductor layer 134 that has a lower height and a greater height than the first fin-type semiconductor layer 132. The sacrificial oxide layer 166 may be an insulating layer that is formed of the same material as the second gate insulating layer 176 illustrated in FIG. 2.

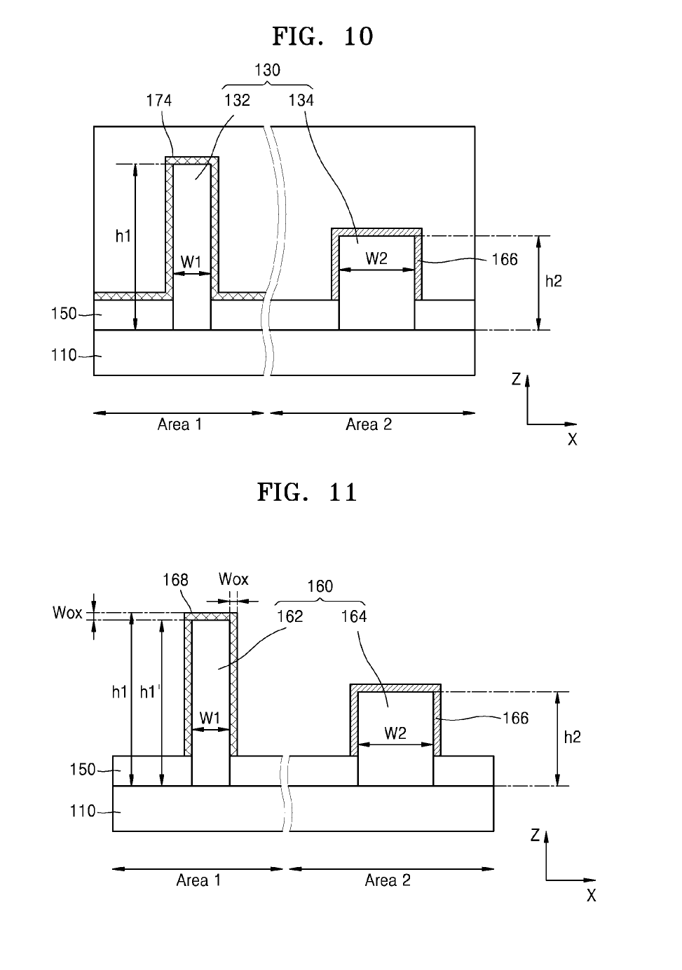

Referring to FIG. 10, the first gate insulating layer 174 is formed on the top surface of the first fin-type semiconductor layer 132, and the gate electrode 172 that vertically crosses the first fin-type semiconductor layer 132 and the second fin-type semiconductor layer 134 by covering the first gate insulating layer 174 and the sacrificial oxide layer 166.

The first gate insulating layer 174 may be extended by covering the top and side surfaces of the first fin-type semiconductor layer 132 and crossing the first fin-type semiconductor layer 132. The first gate insulating layer 174 may be formed of a high-k dielectric material having a higher dielectric constant than a silicon oxide layer, for example, a dielectric constant in a range from about 10 to about 25. In some embodiments, the first gate insulating layer 174 may be formed of at least one material selected from the group consisting of, for example, hafnium oxide (HfO), hafnium silicon oxide (HfSiO), hafnium oxynitride (HfON), hafnium silicon oxynitride (HfSiON), lanthanum oxide (LaO), lanthanum aluminum oxide (LaAlO), zirconium oxide (ZrON), zirconium silicon oxide (ZrsiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and scandium tantalum oxide (PbScTaO). In some embodiments, the first gate insulating layer 174 may be formed by atomic layer deposition (ALD).

By covering the sacrificial oxide layer 166 and the first gate insulating layer 174, the gate electrode 172 is formed to vertically cross the first fin-type semiconductor layer 132 and the second fin-type semiconductor layer 134. The gate electrode 172 forms the gate structure 170 with the first gate insulating layer 174. The gate electrode 172 may be formed of polysilicon or a conductive material doped with metals. In some embodiments, the gate electrode 172 may include, for example, nickel silicide (NiSi). The gate electrode 172 may be formed by at least one method selected from among, for example, chemical vapor deposition (CVD), physical vapor deposition (PVD) and atomic layer deposition (ALD).

Then, the source areas 132S and 134S (refer to FIG. 3) and the drain areas 132D and 134D may be respectively formed (refer to FIG. 3) by injecting impurities into the first fin-type semiconductor layer 132 and the second fin-type semiconductor layer 134.

The semiconductor device 100 may be manufactured as illustrated in FIGS. 5 through 10. Wirings in the semiconductor device 100 are formed later according to conventional methods. Accordingly, the semiconductor device 100 includes a FinFET of a first fin type and a FinFET of a second fin type different from the first fin type, wherein a fin for manufacturing a logic semiconductor device and a fin for manufacturing an input/output semiconductor device have different shapes.

With reference to FIGS. 5 through 10, the gate structure 170 is formed in a last step of the manufacturing method, but an order of manufacturing the gate structure 170 is not limited thereto. Thus, the gate structure 170 may be formed first or formed in the middle of the manufacturing method.

FIG. 11 is a partial cross-sectional view for explaining another method of manufacturing the semiconductor device 100, according to an exemplary embodiment.

Referring to FIG. 11, a second sacrificial oxide layer 168 is formed by re-oxidizing the first fin-type active layer 162 that is formed through the method of FIG. 8. Since the second sacrificial oxide layer 168 may be formed by oxidizing the first fin-type active layer 162 via an oxidation method such as thermal oxidation, the second sacrificial oxide layer 168 may be, for example, a silicon oxide layer. The second sacrificial oxide layer 168 has a width equal to a value 2Wox obtained by subtracting the first width w1 from the second width w2 a direction (an X direction of FIG. 11) parallel to the top surface of the surface 110, and may have a height equal to a value Wox obtained by subtracting a third height h1′ from the first height h1 along a direction (a Z direction of FIG. 11) perpendicular to the substrate 110.

After the second sacrificial oxide layer 168 is formed, the second sacrificial oxide layer 168 formed on the first area is removed by using an etchant capable of selectively removing the silicon oxide layer. Through the above-described etching method, the first fin-type semiconductor layer 132 having the first width w1 in the X direction and the third height h1′ is formed in the first area, and the second fin-type semiconductor layer 134 having the second width w2 in the X direction and the second height h2 is formed in the second area. In one embodiment, the third height h1′ may be greater than the second height h2, and the first width w1 is less than the second width w2. In another embodiment, a ratio h1′/w1 may be greater than a ratio h2/w2. Then, the semiconductor device 100 may be manufactured through a manufacturing procedure described with reference to FIG. 11.

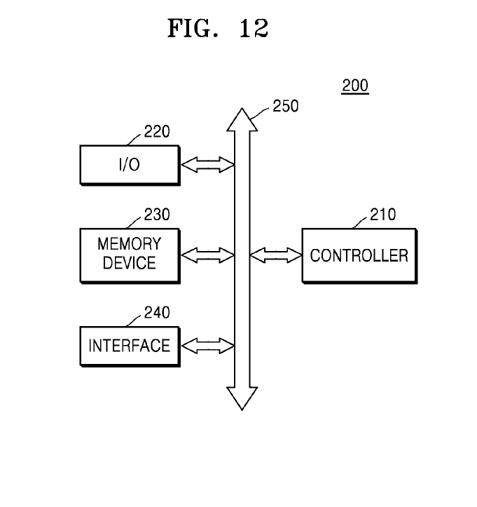

FIG. 12 is a block diagram of an electronic system 200 including the semiconductor devices 100 or 102, according to certain embodiments.

Referring to FIG. 12, the electronic system 200 may include a controller 210, an input/output device (I/O) 220, a memory device 230, an interface 240, and a bus 250. The controller 210, the I/O 220, the memory device 230, and/or the interface 240 may be interconnected through the bus 250.

The controller 210 may include at least one of, for example, a micro processor, a digital signal processor, a micro controller, and logic units that may perform similar functions as the previous devices. The controller 210 may include at least one of the semiconductor devices 100 and 102, wherein the semiconductor device is formed in the first area. The input/output (I/O) 220 may include, for example, a keypad, a keyboard, a display device, or the like. The I/O 220 may include at least one of the semiconductor devices 100 and 102, wherein the semiconductor device is formed in the second area. The memory device 230 may store data, commands, and/or other inputs. The memory device 230 may include at least one of the semiconductor devices 100 and 102, wherein the semiconductor device is formed in the first area of in the second area. Also, the memory device 230 may further include a semiconductor memory device of other type from the semiconductor devices 100 and 102, for example, a non-volatile memory device, a static random access memory (SRAM) device, etc. The interface 240 may receive/transmit data from/to a communication network. The interface 240 may be a wired interface or a wireless interface. For example, the interface 240 may include an antenna, a wired/wireless transceiver, or the like. The interface 240 may include at least one of the semiconductor devices 100 and 102, wherein the semiconductor device is formed in the second area.

The electronic system 200 may be applied to, for example, a personal digital assistant (PDA), a portable computer, a web tablet, a wireless phone, a mobile phone, a digital music player, a memory card, or other electronic device capable of communicating in a wireless environment.

While the inventive concept has been particularly shown and described with reference to exemplary embodiments thereof, it will be understood that various changes in form and details may be made therein without departing from the spirit and scope of the following claims within the scope of the inventive concept.

What is claimed is:

1. A semiconductor device comprising:
a substrate;
a first fin-field effect transistor comprising a first fin-type semiconductor layer formed on the substrate, and a first gate structure covering a first portion of the first fin-type semiconductor layer; and
a second fin-field effect transistor comprising a second fin-type semiconductor layer formed on the substrate, and a second gate structure covering a first portion of the second fin-type semiconductor layer,
wherein the first fin-field effect transistor and the second fin-field effect transistor are separated by a predetermined distance,
wherein the first fin-type semiconductor layer has a first width (w1) between a first surface and a second surface opposite to the first surface in a first direction, and a first height (h1) in a second direction perpendicular to both a top surface of the substrate and the first direction,
wherein the second fin-type semiconductor layer has a second width (w2) between a third surface and a fourth surface opposite to the third surface in the first direction, and a second height (h2) in the second direction,
wherein a first ratio h1/w1 is greater than a second ratio h2/w2, and the first height (h1) is greater than the second height (h2),
wherein the first fin-field effect transistor is formed in a first area where a logic semiconductor device is formed, and
wherein the second fin-field effect transistor is formed in a second area where an input/output (I/O) semiconductor device is formed.

2. The semiconductor device of claim 1, wherein the first gate structure has a first gate insulating layer and a first gate electrode disposed on the first gate insulating layer, and
wherein the second gate structure has a second gate insulating layer formed of a different material from the first gate insulating layer and a second gate electrode disposed on the second gate insulating layer.

3. The semiconductor device of claim 2, wherein the first width (w1) is less than the second width (w2).

4. The semiconductor device of claim 1, wherein the second width (w2) is the width of the second fin-type semiconductor layer at the center of the second height (h2), and
wherein the second fin-type semiconductor layer has a tapered shape including a top width at a top surface of the first portion of the second fin-type semiconductor layer and a bottom width at a bottom of the first portion of the second fin-type semiconductor layer, the bottom width greater than the top width.

5. The semiconductor device of claim 2, wherein the first ratio h1/w1 of the first fin-type semiconductor layer is in a range from about 3.5 to about 9.

6. The semiconductor device of claim 1, wherein each of the first and second fin-type semiconductor layers includes a source region and a drain region, and
wherein the first portion of the first fin-type semiconductor layer and the first portion of the second fin-type semiconductor layer are each a channel area disposed between corresponding source region and drain regions.

7. The semiconductor device of claim 6, wherein each channel area is formed of at least one of silicon (Si), doped silicon, germanium (Ge), and group III-V semiconductor materials.

8. A semiconductor device comprising:
a substrate;
a first fin-field effect transistor comprising a first fin-type semiconductor layer formed on the substrate, and a first gate electrode covering a first portion of the first fin-type semiconductor layer, the first portion having a first height (h1) between a top surface and a bottom surface of the first fin-type semiconductor layer in a first direction, and having a first width (w1) between a first surface and a second surface opposite to the first surface of the first fin-type semiconductor layer in a second direction perpendicular to the first direction and parallel to a top surface of the substrate; and
a second fin-field effect transistor comprising a second fin-type semiconductor layer formed on the substrate, and a second gate electrode covering a first portion of the second fin-type semiconductor layer, the first portion having a second height (h2) between a top surface and a bottom surface of the second fin-type semiconductor layer in the first direction, and having a second width (w2) at the center of the second height (h2) between a third surface and a fourth surface opposite to the third surface of the second fin-type semiconductor layer in the second direction,
wherein a width at the top surface of the first fin-type semiconductor layer between the first surface and the second surface of the first fin-type semiconductor layer is substantially the same as a width at the bottom surface of first fin-type semiconductor layer between the first surface and the second surface of the first fin-type semiconductor layer, and
wherein a width at the top surface of the second fin-type semiconductor layer between the third surface and the fourth surface of the second fin-type semiconductor layer is less than a width at the bottom surface of second fin-type semiconductor layer between the third surface and the fourth surface of the second fin-type semiconductor layer.

9. The semiconductor device of claim 8, wherein the first fin-field effect transistor and the second fin-field effect transistor are separated by a predetermined distance.

10. The semiconductor device of claim 8, wherein the first fin-field effect transistor is formed in a first area where a logic semiconductor device is formed, and
the second fin-field effect transistor is formed in a second area where an input/output (I/O) semiconductor device is formed.

11. The semiconductor device of claim 10, wherein a height of the first fin-type semiconductor layer in the first direction is a greater than that of the second fin-type semiconductor layer.

12. The semiconductor device of claim 10, wherein a width of the first fin-type semiconductor layer in the second direction is a less than a width average value of the second fin-type semiconductor layer in the second direction.

13. The semiconductor device of claim 10, wherein an angle between the third or the fourth surface of the second fin-type semiconductor layer and the top surface thereof is between about 60 degrees and about 85 degrees.

14. The semiconductor device of claim 10, wherein an aspect ratio h2/w2 of the second fin-type semiconductor layer is smaller than an aspect ratio h1/w1 of the first fin-type semiconductor layer.

15. The semiconductor device of claim 14, wherein the aspect ratio h2/w2 of the second fin-type semiconductor layer is between about 2.5 and about 4.

16. A semiconductor device comprising:
a substrate including a top surface and a bottom surface;
a first fin-field effect transistor including a first source, a first drain, a first channel disposed between the first source and the first drain, and a first gate structure covering the first channel, the first channel having a first width (w1) in a first direction parallel to the top surface of the substrate and a first height (h1) in a second direction perpendicular to the first direction; and
a second fin-field effect transistor including a second source, a second drain, a second channel disposed between the second source and the second drain, and a second gate structure covering the second channel, the second channel having a second width (w2) in the first direction and a second height (h2) in the second direction,
wherein the first height (h1) is greater than the second height (h2), and
wherein the first width (w1) is less than the second width (w2).

17. The semiconductor device of claim 16, further comprising:
a logic circuit including one or more logic transistors; and
an input/output circuit including one or more input/output transistors,
wherein the first fin-field effect transistor is one of the logic transistors, and the second fin-field effect transistor is one of the input/output transistors or is an analog transistor.

18. The semiconductor device of claim 16, wherein a width at a top surface of the first channel in the second direction is substantially the same as a width at a bottom surface of the first channel in the second direction, and
wherein a width at a top surface of the second channel in the second direction is less than a width at a bottom surface of the second channel in the second direction.

19. The semiconductor device of claim 18, wherein an angle between the top surface of the second channel and a first surface or a second surface opposite to the first surface of the second channel in the second direction is between 60 degrees and 85 degrees.

20. The semiconductor device of claim 16, wherein the first gate structure has a first gate insulating layer and a first gate electrode disposed on the first gate insulating layer, and
wherein the second gate structure has a second gate insulating layer formed of a different material from the first gate insulating layer and a second gate electrode disposed on the second gate insulating layer.
